(19) United States
(12) Patent Application Publication
(10) Pub. No.: US 2026/0262357 A1
(43) Pub. Date: Sep. 3, 2026

(54) CLUSTERING SET OF LEDS TO ENHANCE COLOR UNIFORMITY

(71) Applicant: SIGNIFY HOLDING B.V., EINDHOVEN (NL)

(72) Inventor: JOHANNES PETRUS MARIA ANSEMS, HULSEL (NL)

(21) Appl. No.: 19/164,639

(22) PCT Filed: Mar. 11, 2024
(86) PCT No.: PCT/EP2024/056326

§ 371 Date: Sep. 12, 2025

(30) Foreign Application Priority Data
Mar. 16, 2023 (EP) 23162262.2

(51) Int. Cl. H10H 29/855; F21S 8/02; F21V 9/02; F21Y 105/16; F21Y 113/13; F21Y 115/10; H10H 20/855; H10H 29/24

(52) U.S. Cl. CPC H10H 29/855; F21S 8/026; F21V 9/02; H10H 20/855; H10H 29/24; F21Y 2105/16; F21Y 2113/13; F21Y 2115/10

(57) ABSTRACT

The invention provides a light generating system comprising a plurality of n1 lighting modules and a diffuser element, wherein: (a) each lighting module comprises a module array of n2 sets of light generating devices; wherein n1≥2 and n2≥3; (b) each light generating device comprises a solid state light source and a lens, wherein the solid state light source is configured to generate light source light, wherein the lens is configured downstream of the solid state light source and configured to beam shape the light source light into beam shaped device light; (c) each set comprises a set array of n3 light generating devices comprising two types of light generating devices, wherein the two types of light generating devices comprise a first type of light generating devices and a second type of light generating devices, wherein the two types of light generating devices differ in spectral distributions of the device light, and wherein the two types of light generating devices are positioned symmetrically in the set array; wherein n3 is selected from the range of 4≤n3<6; (d) a first distance (d1) between solid state light sources within a set array is smaller than a second distance (d2) between solid state light sources from different set arrays; (e) the diffuser element is configured downstream of the n1 lighting modules; wherein the diffuser element is transmissive for at least part of the device light; and (f) the light generating system is configured to generate system light, wherein the system light comprises diffused device light emanating from the diffuser element.

### FIELD OF THE INVENTION

The invention relates to a light generating system. Also, the invention relates to a lighting device comprising the light generating system. Further, the invention relates to an arrangement comprising the light generating system.

### BACKGROUND OF THE INVENTION

Light emitting modules are known in the art. US2013249407, for instance, describes a first LED group including a plurality of LEDs regularly arranged in a toric shape on the circumference of a center of an approximately rectangular substrate which is formed of ceramics. In addition, the first LED group including the plurality of LEDs is entirely covered in a toric shape with a sealing member. In addition, a second LED group including a plurality of LEDs is regularly arranged in a grid shape in the vicinity of the center of the approximately rectangular substrate. In addition, the LED group including the plurality of LEDs is entirely covered with a sealing member. In addition, the sealing member entirely covers the inside of the toric portion of a first region.

US2013/201674A1 discloses a modular lighting fixture assembly. Multiple light pods can be removably mounted on both lateral sides of a mechanical thermal element, such as an elongated heat sink. The pods can be easily removed for cleaning, maintenance, and transport, for example. A light strip including multiple LEDs can be mounted to a surface of the heat sink on both sides. Each pod has a portion cutaway such that when the pods are mounted to the heat sink, the cutaway portions align with the light strips. When mounted, the light strip can be adjacent to or protrude into an interior cavity of the pod. The interior surfaces of the pods are shaped to redirect light in a particular output profile. The assembly may be mounted to a ceiling and used as an overhead fixture designed to efficiently light an aisle in a retail space or a storage facility.

WO2017/090956A discloses a light source module that comprises a circuit board and a plurality of light-emitting diodes arranged on the circuit board, wherein the plurality of light-emitting diodes comprise a plurality of first light-emitting diodes connected to a power input terminal, and a plurality of second light-emitting diodes connected to an output terminal of the plurality of first light-emitting diodes, the plurality of first light-emitting diodes are spaced apart from each other, and at least two of the plurality of second light-emitting diodes are disposed between the respective first light-emitting diodes.

### SUMMARY OF THE INVENTION

In current times, people may have to spend a lot of time indoors especially in situations where people may have to work or attend school from a home environment. Hence, it is very beneficial to have access or exposure to natural daylight in such environment.

Natural daylight has a positive effect on an individual's health, especially in the production of Vitamin-D. Further, natural light may become increasingly important in the future where the current trend appears to promote working indoors. A solution may be the use of an artificial daylight, such as a skylight, which may provide an illusion of sunlight. Artificial daylights may provide emulation of at least certain aspects of an outdoor environment in an indoor environment. The demand for artificial daylights is increasing due to its beneficial properties for human wellbeing. Since people tend to spend a majority of their day indoors, which may remove them from natural daylight, there is an interest in creating artificial light, which may simulate the appearance and light of a natural window or daylight. Thus, there appears to be a desire for (improved) artificial daylights, or other type of lighting devices or light generating systems, having enhanced natural appearance. Current systems may show a lack of (color) uniformity between a first group of light sources and a second group of light sources.

Hence, it is an aspect of the invention to provide an alternative light generating system which preferably further at least partly obviates one or more of above-described drawbacks. The present invention may have as object to overcome or ameliorate at least one of the disadvantages of the prior art, or to provide a useful alternative. Especially, the light generating system according to the present invention may provide clusters of light sources having an enhanced (color) uniformity.

According to a first aspect, the invention provides a light generating system comprising a plurality of n1 lighting modules and a diffuser element. In embodiments, each lighting module may comprise a module array of n2 sets of light generating devices. In embodiments n1≥2. In further embodiments, n2≥3. Each light generating device may in embodiments comprise a solid state light source and a lens. Especially, the solid state light source may be configured to generate light source light (in an operational mode of the system). In embodiments, the lens may be configured downstream of the solid state light source. Especially, the lens may in embodiments be configured to beam shape the light source light into beam shaped device light. In embodiments, each set may comprise a set array of n3 light generating devices. Especially, each set array of n3 light generating devices may in embodiments comprise two types of light generating devices. In embodiments, the two types of light generating devices may comprise a first type of light generating devices and a second type of light generating devices. The two types of light generating devices may in embodiments differ in spectral distributions of the (beam shaped) device light. In further embodiments, the two types of light generating devices may be positioned symmetrically in the set array. In embodiments, n3 may be selected from the range of 4≤n3≤6. In embodiments, a first distance (d1) between solid state light sources within a set array may be smaller than a second distance (d2) between solid state light sources from different set arrays. The diffuser element may in embodiments be configured downstream of the n1 lighting modules. In embodiments, the diffuser element may be transmissive for at least part of the device light. In embodiments, the light generating system may (in an operational mode) be configured to generate system light. The system light may in embodiments comprise diffused device light emanating from the diffuser element. Hence, in specific embodiments, the invention provides a light generating system comprising a plurality of n1 lighting modules and a diffuser element, wherein: (a) each lighting module comprises a module array of n2 sets of light generating devices; wherein n1≥2 and n2≥3; (b) each light generating device comprises a solid state light source and a lens, wherein the solid state light source is configured to generate light source light, wherein the lens is configured downstream of the solid state light source and configured to beam shape the light source light into beam shaped device light; (c) each set comprises a set array of n3 light generating devices comprising two types of light generating devices, wherein the two types of light generating devices comprise a first type of light generating devices and a second type of light generating devices, wherein the two types of light generating devices differ in spectral distributions of the device light, and wherein the two types of light generating devices are positioned symmetrically in the set array; wherein n3 is selected from the range of 4≤n3≤6; (d) a first distance (d1) between solid state light sources within a set array is smaller than a second distance (d2) between solid state light sources from different set arrays; (e) the diffuser element is configured downstream of the n1 lighting modules; wherein the diffuser element is transmissive for at least part of the device light; and (f) the light generating system is configured to generate system light, wherein the system light comprises diffused device light emanating from the diffuser element.

With such light generating system, a plurality of light sources may be configured to provide system light having a high color and/or luminance uniformity. Further, with such light generating system, it may be possible to have adjacent modules appearing (more) seamless.

As indicated above, the light generating system may comprise a plurality of n1 lighting modules. In embodiments n1≥2, such as n1≥3, especially n1≥5, like n126. In further embodiments, n1≥10, such as n1≥20, like n1≥30. Additionally or alternatively, in embodiments n1≤1000, such as n1≤500, especially n1≤200. Especially, each lighting module may in embodiments comprise a module array of n2 sets of light generating devices. In embodiments, the module array may be a linear array. In such embodiments, the module array may be a 1*n2 array. In embodiments n2≥3, such as n2≥4, especially n2≥6. In further embodiments n2≥10, such as n2≥20, like n2≥30. Additionally or alternatively, in embodiments n2≤500, such as n2≤200, especially n2≤75. In such embodiments, two or more lighting modules may be configured parallel to one another. Additionally or alternatively, two or more lighting modules may in embodiments be configured orthogonal to one another, see also further below. Additionally or alternatively, the lighting modules may in embodiments be arranged in a 2D plane. However, other configurations are herein not excluded.

Each set may in embodiments comprise a set array of n3 light generating devices. Especially, each set array of n3 light generating devices may in embodiments comprise two types of light generating devices. Especially, the two types of light generating devices may in embodiments comprise a first type of light generating devices and a second type of light generating devices. In embodiments, the first type of light generating devices may (in an operational mode) be configured to provide first device light, wherein the first device light has a first spectral distribution. Similarly, the second type of light generating devices may (in an operational mode) be configured to provide second device light, wherein the second device light has a second spectral distribution. In embodiments, the first spectral distribution and the second spectral distribution may differ, see further below. Hence, the two types of light generating devices may in embodiments differ in spectral distributions of the device light. In further embodiments, the two types of light generating devices may in embodiments be positioned symmetrically in the set array. Positioning of the two types of light generating devices is discussed further below. In embodiments, n3 may be selected from the range of 4≤n3≤8, such as from the range of 4≤n3≤6. In specific embodiments, n3=4. In alternative embodiments, n3=5. In yet further embodiments, n3=6.

Thus, in specific embodiments, the light generating system may comprise n1 lighting modules, each lighting module may comprise (a module array of) n2 sets of light generating devices, wherein each set of light generating devices may comprise (a set array of) n3 light generating devices.

In embodiments, the light generating devices may comprise solid state light sources. Especially, each light generating device may in embodiments comprise a solid state light source. In embodiments, the solid state light source may be selected from the group of a COB, a LED, a diode laser, and a superluminescent diode. Each light generating device may in embodiments further comprise a lens. Especially, the solid state light source may be configured to generate light source light (in an operational mode of the system). In embodiments, the lens may be configured downstream of the solid state light source.

Especially, the lens may in embodiments be configured to beam shape the light source light into beam shaped device light. In further embodiments, the two types of light generating devices may differ in spectral distributions of the beam shaped device light.

Within the set array, the solid state light sources may be configured at a first distance (d1). The first distance (d1) may be defined as a heart to heart distance between nearest neighboring solid state light sources within a set array. Between two adjacent set arrays, the solid state light sources may be configured at a second distance (d2). The second distance (d2) may be defined as a heart to heart distance between nearest neighboring solid state light sources from different set arrays within the same lighting module. In embodiments, the first distance (d1) between solid state light sources within a set array may be smaller than the second distance (d2) between solid state light sources from different set arrays. Thus, in embodiments d1<d2. Especially, in embodiments d1≤1.1*d2, such as d1≤1.5*d2, like d1≤2*d2.

In further embodiments, the first distance (d1) may be selected from the range of 1-50 mm, such as selected from the range of 2-30 mm, especially selected from the range of 5-25 mm, more especially selected from the range of 10-20 mm. Hence, in specific embodiments, the first distance (d1), defined as a heart to heart distance between nearest neighboring solid state light sources within a set array, is selected from the range of 5-25 mm.

The second distance (d2) may in embodiments be selected from the range of 20-75 mm, especially selected from the range of 30-65 mm, more especially selected from the range of 40-55 mm. Hence, in specific embodiments, the second distance (d2), defined as a heart to heart distance between nearest neighboring solid state light sources from different set arrays within the same lighting module, is selected from the range of 20-75 mm.

In further embodiments, the light generating system may have a third distance (d3). The third distance (d3) may in embodiments be defined as a heart to heart distance between nearest neighboring solid state light sources from different set arrays from different lighting modules. The third distance (d3) may in embodiments be selected from the range of 50-140 mm, especially selected from the range of 65-125 mm, more especially selected from the range of 85-105 mm. Hence, in specific embodiments, a third distance (d3), defined as a heart to heart distance between nearest neighboring solid state light sources from different set arrays from different lighting modules, is selected from the range of 50-140 mm.

As indicated above, the light generating system may in embodiments further comprise a diffuser element. The diffuser element may in embodiments be configured downstream of the n1 lighting modules. In embodiments, the diffuser element may be transmissive for at least part of the device light. The diffuser element may in embodiments comprise one or more of glass and polymeric material. In embodiments, the diffuser element may comprise polycarbonate (PC) (or e.g. PMMA). Hence, the diffuser element may be translucent. In embodiments, the light generating system may (in an operational mode) be configured to generate system light. The system light may in embodiments comprise diffused device light emanating from the diffuser element. In embodiments, the diffuser element may provide a (substantially) Lambertian distribution of the system light. In embodiments, at least part of the (first and second) device light may be reflected by the diffuser element (and of course at least part of the (first and second) device light may be transmitted by the diffuser element). The diffuser element may in embodiments have a transmission selected from the range of 40-80%, such as selected from the range of 50-70%. In further embodiments, the diffuser element may provide a (substantially) Lambertian distribution of the system light. In such embodiments, the system light may comprise a degree of light diffusion selected from the range of 2×45° to 2×60°. Herein, 2×45° refers to a full width half maximum angle of 90°, and 2×60° refers to a full width half maximum angle of 120°.

In further embodiments, components of the light generating system, especially components at an interior of the light generating system, may be reflective for the (first and second) device light. Reflective may herein refer to reflecting at least 70%, such as at least 80%, especially at least 90% of light under perpendicular irradiation. In this way, the light generating system may have a high efficiency.

As indicated above, the two types of light generating devices may comprise a first type of light generating devices and a second type of light generating devices. In embodiments, the first type of light generating devices may be configured to generate first device light having a first spectral distribution. The second type of light generating devices may in embodiments be configured to generate second device light having a second spectral distribution. The terms “first” and “second” herein may especially not be indicating any order or positioning but may be used to distinguish the two types of light generating devices and their respective device light.

In embodiments, the first device light may be selected from visible light. In further embodiments, the first device light may be selected from white light and colored light. Similarly, the second device light may in embodiments be selected from visible light. In further embodiments, the second device light may be selected from white light and colored light. Visible light may herein refer to light having one or more wavelengths selected from the range of 380-780 nm.

In specific embodiments, the first device light may comprise warm white light. In such embodiments, the first type of light generating devices may be configured to generate warm white first device light. Warm white (first device) light may herein refer to light having a CCT of at most 4000 K, such as at most 3500 K, especially at most 3000 K, like at maximum 2500 K. In specific embodiments, the second device light may comprise cool white light. In such embodiments, the second type of light generating devices may be configured to generate cool white second device light. Cool white (second device) light may herein refer to light having a CCT of at 3000 K, like at least 3500 K, more especially at least 4000 K, especially at least 4500 K, such as at least at least 5000 K, like at least 6000 K. In embodiments, the warm white first device light and the cool white second device light may have a difference in correlated color temperature of, especially at least 300 K, such as at least 500 K, especially at least 1000 K, more especially at least 1500 K, such as at least 2500 K, like at least 3500 K. Hence, in specific embodiments the two types of light generating devices comprise a first type of light generating devices configured to generate warm white first device light and a second type of light generating devices configured to generate cool white second device light, wherein the warm white first device light and the cool white second device light have a difference in correlated color temperature of at least 500 K. In such embodiments, the two types of light generating devices may together provide different hues of white system light, depending on their relative intensities.

As the terms “first” and “second” may especially not be indicating any order or positioning, in alternative embodiments, the first type of light generating devices may be configured to generate cool white first device light and/or the second type of light generating devices may be configured to generate warm white second device light. However, for the sake of clarity, inverse embodiments may not be specifically indicated although they may be part of the invention. In yet further embodiments, at least one of the two types of light generating devices may be configured to generate colored light, especially blue light.

In further embodiments, the first device light may have (the first spectral distribution having) a first correlated color temperature CCT1. Especially, the warm white first device light may have a first correlated color temperature CCT1 of at most 4000 K, such as at most 3500 K, especially at most 3000 K, like at maximum 2500 K. In further embodiments, the warm white first device light may have a first correlated color temperature CCT1 selected from the range of 1500-4000 K, such as selected from the range of 1800-3500 K, especially selected from the range of 2000-3000 K. Similarly, the second device light may have (the second spectral distribution having) a second correlated color temperature CCT2. Especially, the cool white second device light may have a second correlated color temperature CCT2 selected from the range of at least 3000 K, such as at least 3500 K, like at least 4000 K, especially at least 4500 K, such as at least at least 5000 K, more especially at least 6000 K. In further embodiments, the cool white second device light may have a second correlated color temperature CCT2 selected from the range of 3000-12000 K, such as from the range of 3500-8000K, especially from the range of 4000-7000 K. In alternative embodiments, the second correlated color temperature CCT2 may be selected from the range of 4000-12000 K, such as from the range of 5000-12000 K, especially form the range of 6000-12000 K. Hence, in specific embodiments, the warm white first device light has a first correlated color temperature CCT1 selected from the range of 1800-3500 K, and wherein the cool white second device light has a second correlated color temperature CCT2 selected from the range of at least 3500 K, with in further specific embodiments |CCT2-CCT1|≥500 K, more especially |CCT2-CCT1|≥1000 K, such as especially |CCT2-CCT1|≥1500 K, like |CCT2-CCT1|>2500 K, such as |CCT2-CCT1|≥3500 K.

As indicated above, the light generating devices may be arranged in a set array. In embodiments, the first type of light generating devices and the second type of light generating devices in each set array may be configured in an ABBA or BAAB configuration. In such embodiment, A may refer to the first type of light generating device or the second type of light generating device and B may refer to the second type of light generating device of the first type of light generating device. Especially, A and B refer to two different types of light generating devices. In such embodiment, n3=4. Hence, in specific embodiments the first type of light generating devices and the second type of light generating devices in each set array are configured in an ABBA or BAAB configuration. In further specific embodiments, n1≥6, n2≥6,and n3=4.

Returning to the lighting modules, in embodiments each lighting module comprises a module array wherein n2 is selected from an even number. Thus, in such embodiments the lighting module may comprise an even number of sets of light generating devices. The module array may have a module middle position. In embodiments, the module array may be configured such that the set arrays may be symmetrically configured relative to the module middle position. Especially, in embodiments wherein n2 is an even number, no set array may be at the module middle position. In such embodiments, the sets of light generating devices may be symmetrically configured relative to the module middle position. Especially, in embodiments wherein n2 is an even number, no set array may be at the module middle position. Hence, in specific embodiments each lighting module comprises a module array wherein n2 is selected from an even number, wherein the module array has a module middle position; and wherein the module array is configured such that the set arrays are symmetrically configured relative to the module middle position, with no set array at the module middle position. In such embodiments, electrical components (other than light generating devices) may be arranged in the module middle position. The electrical components may in embodiments especially comprise one or more of an electrical wire, a control system, a driver, a communication device (such as an antenna).

As indicated above, at least two lighting modules may be configured parallel to one another. Additionally or alternatively, at least two lighting modules may in embodiments be configured orthogonal to one another. Especially, at least two lighting modules may in embodiments be configured parallel to the diffuser element. In further embodiments, each lighting module may be configured parallel to the diffuser element. Hence, in specific embodiments, at least two lighting modules are configured orthogonal to each other. Especially, an ABBA or BAAB configuration of the first type of light generating devices and the second type of light generating devices in each set array may enhance color uniformity and/or intensity uniformity between two orthogonally configured lighting modules.

As indicated above, the module array may have a module middle position. Similarly, the set array may have a set array middle position. Especially, in embodiments, each set array has a set array middle position. Each lighting module may in embodiments further comprise a first end and a second end. In embodiments, one of the first end and the second end of one of the lighting modules may be directed at the set array middle position of one of the set arrays of the other lighting module. Additionally or alternatively, one of the first end and the second end of one of the lighting modules may in embodiments be directed at the module middle position of the other lighting module. Hence, in specific embodiments, each set array has a set array middle position; each lighting module comprises a first end and a second end, wherein one of the first end and the second end of one of the lighting modules is directed at (i) either a set array middle position of one of the set arrays of the other lighting module, (ii) or the module middle position of the other lighting module. In this way, the first light generating devices and second light generating devices together may contribute to a more uniform system light.

Returning to the light generating devices. In embodiments, the light generating devices may be side-emitting light generating devices. Such side-emitting light generating devise may comprise a solid state light source and a side-emitting lens. Such side-emitting lens may direct less than 40%, such as less than 20%, especially less than 10% of device light in a direction perpendicular to the diffuser element. In this way, differences in luminance of the system may be minimized. In other words, “bright spots” may be prevented.

Also, such side-emitting lens may have a lower height (in a direction perpendicular to the diffuser element) compared to standard lenses and therefore may result in a lower height (in a direction perpendicular to the diffuser element) of the light generating system.

In further embodiments, the light generating system may comprise a first light emitting part and a second light emitting part. In embodiments, the first light emitting part may enclose the second light emitting part. Especially, the first light emitting part may in embodiments comprises the plurality of n1 lighting modules and the diffuser element. Hence, in specific embodiments the light generating system comprises a first light emitting part and a second light emitting part, wherein the first light emitting part encloses the second light emitting part, wherein the first light emitting part comprises the plurality of n1 lighting modules and the diffuser element. In embodiments, the first light emitting part may comprise the first type of light generating devices configured to generate warm white first device light and the second type of light generating devices configured to generate cool white second device light. Especially, in such embodiments the first light emitting part may function as an artificial daylight.

The second light emitting part may comprise the first type of light generating devices configured to generate blue first device light and the second type of light generating devices configured to generate cool white second device light. Especially, the first type of light generating devices and the second type of light generating devices of the second light emitting part may be selected from light generating devices configured to generate blue device light and light generating devices configured to generate cool white device light having a correlated color temperature selected from the range of at least 3500 K, more especially at least 4000 K, especially at least 4500 K, such as at least at least 5000 K, like at least 6000 K. Blue (first device) light may comprise light having a peak wavelength selected from the range of 440-490 nm. However, the first device light may also have a peak wavelength in the 400-440 nm wavelength range, especially, however, at least about 430 nm, such as at least about 440 nm. In such embodiments, the second light emitting part may function as an artificial skylight (or in general artificial daylight).

In further embodiments, the second light emitting part may share the diffuser element. Additionally or alternatively, the second light emitting part may in embodiments comprise a second diffuser element. In embodiments, the first light emitting part may comprise a first diffuser element. The first diffuser element may in embodiments have a transmission selected from the range of 40-80%, such as selected from the range of 50-70%. In further embodiments, the first diffuser element may provide a (substantially) Lambertian distribution of (primary) system light. In such embodiments, the (primary) system light may comprise a degree of light diffusion selected from the range of 2×45° to 2×60° (see also above). In embodiments, the second light emitting part may also comprise the first diffuser element. In alternative embodiments, the second light emitting part may comprise a second diffuser element. The second diffuser element may in embodiments have a transmission selected from the range of 50-90%, such as selected from the range of 70-85%. In further embodiments, the second diffuser element may provide (secondary) system light comprising a degree of light diffusion selected from the range of 2×25° to 2×45°. In yet further embodiments, the first diffuser element may provide (primary) system light comprising a degree of light diffusion which may differ at least 2×10° from the degree of light diffusion of the (secondary) system light provided by the second diffuser element. Transmission may herein refer to transmission of light under perpendicular irradiation. In this way, the light generating system may have a high efficiency. Herein, 2×25° refers to a full width half maximum angle of 50°.

Hence, in specific embodiments, the light generating system may comprise a first light emitting part and a second light emitting part, wherein the first light emitting part encloses the second light emitting part, wherein the first light emitting part comprises a plurality of n1 lighting modules and a diffuser element, wherein: (a) each lighting module comprises a module array of n2 sets of light generating devices; wherein n1≥2 and n2≥3; (b) each light generating device comprises a solid state light source and a lens, wherein the solid state light source is configured to generate light source light, wherein the lens is configured downstream of the solid state light source and configured to beam shape the light source light into beam shaped device light; (c) each set comprises a set array of n3 light generating devices comprising two types of light generating devices, wherein the two types of light generating devices comprise a primary first type of light generating devices and a primary second type of light generating devices, wherein the two types of light generating devices differ in spectral distributions of the device light, and wherein the two types of light generating devices are positioned symmetrically in the set array; wherein n3 is selected from the range of 4≤n3≤6; (d) a first distance (d1) between solid state light sources within a set array is smaller than a second distance (d2) between solid state light sources from different set arrays; (e) the diffuser element is configured downstream of the n1 lighting modules; wherein the diffuser element is transmissive for at least part of the device light; (f) the light generating system is configured to generate system light, wherein the system light comprises diffused device light emanating from the diffuser element; (g) the primary first type of light generating devices are configured to generate warm white primary first device light, and the primary second type of light generating devices are configured to generate cool white primary second device light; wherein the second light emitting part comprises a plurality of n1 lighting modules and a diffuser element, wherein: (i) each lighting module comprises a module array of n2 sets of light generating devices; wherein n1≥2 and n2≥3; (ii) each light generating device comprises a solid state light source and a lens, wherein the solid state light source is configured to generate light source light, wherein the lens is configured downstream of the solid state light source and configured to beam shape the light source light into beam shaped device light; (iii) each set comprises a set array of n3 light generating devices comprising two types of light generating devices, wherein the two types of light generating devices comprise a secondary first type of light generating devices and a secondary second type of light generating devices, wherein the two types of light generating devices differ in spectral distributions of the device light, and wherein the two types of light generating devices are positioned symmetrically in the set array; wherein n3 is selected from the range of 4≤n3≤6; (iv) a first distance (d1) between solid state light sources within a set array is smaller than a second distance (d2) between solid state light sources from different set arrays; (v) the diffuser element is configured downstream of the n1 lighting modules; wherein the diffuser element is transmissive for at least part of the device light; (vi) the light generating system is configured to generate system light, wherein the system light comprises diffused device light emanating from the diffuser element; and (vii) the secondary first type of light generating devices are configured to generate blue secondary first device light, and the secondary second type of light generating devices are configured to generate cool white primary second device light.

The term “first light emitting part”, and similar terms, may refer to a (first) part that may emit light during operation of the light generating system. Likewise, the term “second light emitting part”, and similar terms, may refer to a (second) part that may emit light during operation of the light generating system.

Especially, the first light emitting part may be configured to provide primary system light. Similarly, the second light emitting part may be configured to provide secondary system light. The system light may in embodiments comprise one or more of the primary system light and the secondary system light. In embodiments, the primary system light may comprise light generated by one or more of the primary first type of light generating devices and the primary second type of light generating devices. Similarly, the secondary system light may in embodiments comprise light generated by one or more of the secondary first type of light generating devices and the secondary second type of light generating devices. In such embodiments, the first light emitting part and the second light emitting part may be separated by a wall. In this way, light generated in the first light emitting part may in embodiments be prevented from entering the second light emitting part. Similarly, light generated in the second light emitting part may in embodiments be prevented from entering the first light emitting part. In further embodiments, the wall may also separate the first diffuser element and the second diffuser element. In embodiments wherein the second light emitting part comprises the first diffuser element, light generated in the first light emitting part may in embodiments exit the second light emitting part and light generated in the second light emitting part may in embodiments exit the first light emitting part as a result of internal reflection of the (first) diffuser element. Hence, in embodiments (during operation of both the first light emitting part and the second light emitting part) at most 5% especially at most 1% of the primary system light may comprise light generated by the secondary first type of light generating devices and the secondary second type of light generating devices. Additionally or alternatively, (during operation of both the first light emitting part and the second light emitting part) at most 5% especially at most 1% of the secondary system light may in embodiments comprise light generated by the primary first type of light generating devices and the primary second type of light generating devices.

The first light emitting part and a second light emitting part may be comprised by a single light emitting unit, which may be suspend from a ceiling, be integrated in a ceiling, configured at a wall, or integrated in a wall, etc.

Further, adjacent (different) light emitting parts may, with the present invention, appear (more) seamless.

In further embodiments, the light generating devices may be configured in an ABBA or BAAB configuration in each set array in the first light emitting part. Additionally or alternatively, the light generating devices may in embodiments be configured in an ABBA or BAAB configuration in each set array in the second light emitting part.

Especially, embodiments described above in relation to the first type of light generating devices may also apply to the primary first type of light generating devices and/or the secondary first type of light generating devices. Similarly, embodiments described above in relation to the second type of light generating devices may also apply to the primary second type of light generating devices and/or the secondary first type of light generating devices.

The light generating system may in embodiments further comprise a control system. The control system may especially be configured to control one or more of an intensity and hue of the system light. In embodiments, the control system may control one or more of an intensity of the first type of light generating devices and an intensity of the second type of light generating devices. In specific embodiments, the control system may control one or more of an intensity of the primary first type of light generating devices and an intensity of the primary second type of light generating devices. In further specific embodiments, the control system may control one or more of an intensity of the secondary first type of light generating devices and an intensity of the secondary second type of light generating devices. In further embodiments, the control system may control the system light depending on one or more of time, local weather, relative position of the sun, and input via a user interface. See also below. In embodiments, the control system may increase one or more of a light intensity on a sunny day compared to a cloudy day.

The terms “upstream” and “downstream” relate to an arrangement of items or features relative to the propagation of the light from a light generating means (here the especially the light source), wherein relative to a first position within a beam of light from the light generating means, a second position in the beam of light closer to the light generating means is “upstream”, and a third position within the beam of light further away from the light generating means is “downstream”.

The light generating system may be part of or may be applied in e.g. office lighting systems, household application systems, shop lighting systems, home lighting systems, accent lighting systems, theater lighting systems, decorative lighting systems, portable systems, green house lighting systems, horticulture lighting. The light generating system (or luminaire) may be part of or may be applied in e.g. optical communication systems or disinfection systems.

Preferably, the light source is a light source that during operation emits (light source light) at least light at a wavelength selected from the range of 200-490 nm, especially a light source that during operation emits at least light at wavelength selected from the range of 400-490 nm, even more especially in the range of 440-490 nm. This light may partially be used by the wavelength converter nanoparticles (see further also below). Hence, in a specific embodiment, the light source is configured to generate blue light.

The term “white light”, and similar terms, herein, is known to the person skilled in the art. It may especially relate to light having a correlated color temperature (CCT) between about 1800 K and 20000 K, such as between 2000 and 20000 K, especially 2700-20000 K, for general lighting especially in the range of about 2000-7000 K, such as in the range of 2700 K and 6500 K. In embodiments, e.g. for backlighting purposes, or for other purposes, the correlated color temperature (CCT) may especially be in the range of about 7000 K and 20000 K. Yet further, in embodiments the correlated color temperature (CCT) is especially within about 15 SDCM (standard deviation of color matching) from the BBL (black body locus), especially within about 10 SDCM from the BBL, even more especially within about 5 SDCM from the BBL. The terms “visible”, “visible light” or “visible emission” and similar terms refer to light having one or more wavelengths in the range of about 380-780 nm. Herein, UV may especially refer to a wavelength selected from the range of 190-380 nm, such as 200-380 nm. The term “colored light” may in embodiments refer to visible light that is not white light. In embodiments, colored light may be visible light having a color point at least 15 SDCM from the BBL.

The terms “light” and “radiation” are herein interchangeably used, unless clear from the context that the term “light” only refers to visible light. The terms “light” and “radiation” may thus refer to UV radiation, visible light, and IR radiation. In specific embodiments, especially for lighting applications, the terms “light” and “radiation” refer to (at least) visible light. The terms “blue light” or “blue emission”, and similar terms, may especially relate to light having a wavelength in the range of about 440-490 nm (including some violet and cyan hues). In specific embodiments, the blue light may have a centroid wavelength in the 440-490 nm range. The phrase “light having one or more wavelengths in a wavelength range” and similar phrases may especially indicate that the indicated light (or radiation) has a spectral power distribution with at least intensity or intensities at these one or more wavelengths in the indicate wavelength range. For instance, a blue emitting solid state light source will have a spectral power distribution with intensities at one or more wavelengths in the 440-495 nm wavelength range. In specific embodiments, especially for lighting applications, the terms “light” and “radiation” refer to visible light. Herein, the term “visible light” especially relates to light having a wavelength selected from the range of 380-780 nm.

The term “controlling” and similar terms especially refer at least to determining the behavior or supervising the running of an element. Hence, herein “controlling” and similar terms may e.g. refer to imposing behavior to the element (determining the behavior or supervising the running of an element), etc., such as e.g. measuring, displaying, actuating, opening, shifting, changing temperature, etc. Beyond that, the term “controlling” and similar terms may additionally include monitoring. Hence, the term “controlling” and similar terms may include imposing behavior on an element and also imposing behavior on an element and monitoring the element. The controlling of the element can be done with a control system, which may also be indicated as “controller”. The control system and the element may thus at least temporarily, or permanently, functionally be coupled. The element may comprise the control system. In embodiments, the control system and element may not be physically coupled. Control can be done via wired and/or wireless control. The term “control system” may also refer to a plurality of different control systems, which especially are functionally coupled, and of which e.g. one control system may be a master control system and one or more others may be slave control systems. A control system may comprise or may be functionally coupled to a user interface.

The control system may also be configured to receive and execute instructions from a remote control. In embodiments, the control system may be controlled via an App on a device, such as a portable device, like a Smartphone or I-phone, a tablet, etc. The device is thus not necessarily coupled to the lighting system but may be (temporarily) functionally coupled to the lighting system.

Hence, in embodiments the control system may (also) be configured to be controlled by an App on a remote device. In such embodiments the control system of the lighting system may be a slave control system or control in a slave mode. For instance, the lighting system may be identifiable with a code, especially a unique code for the respective lighting system. The control system of the lighting system may be configured to be controlled by an external control system which has access to the lighting system on the basis of knowledge (input by a user interface of with an optical sensor (e.g. QR code reader) of the (unique) code. The lighting system may also comprise means for communicating with other systems or devices, such as on the basis of Bluetooth, Thread, WIFI, LiFi, ZigBee, BLE or WiMAX, or another wireless technology.

The system, or apparatus, or device may execute an action in a “mode” or “operation mode” or “mode of operation” or “operational mode”. The term “operational mode may also be indicated as “controlling mode”. Likewise, in a method an action or stage, or step may be executed in a “mode” or “operation mode” or “mode of operation” or “operational mode”. This does not exclude that the system, or apparatus, or device may also be adapted for providing another controlling mode, or a plurality of other controlling modes. Likewise, this may not exclude that before executing the mode and/or after executing the mode one or more other modes may be executed.

However, in embodiments a control system may be available, that is adapted to provide at least the controlling mode. Would other modes be available, the choice of such modes may especially be executed via a user interface, though other options, like executing a mode in dependence of a sensor signal or a (time) scheme, may also be possible. The operation mode may in embodiments also refer to a system, or apparatus, or device, which can only operate in a single operation mode (i.e. “on”, without further tunability).

Hence, in embodiments, the control system may control in dependence of one or more of an input signal of a user interface, a sensor signal (of a sensor), and a timer. The term “timer” may refer to a clock and/or a predetermined time scheme.

In yet a further aspect, the invention also provides a lamp or a luminaire comprising the light generating system as defined herein. The luminaire may further comprise a housing, optical elements, louvres, etc. etc. . . The lamp or luminaire may further comprise a housing enclosing the light generating system. The lamp or luminaire may comprise a light window in the housing or a housing opening, through which the system light may escape from the housing. In yet a further aspect, the invention also provides an optical wireless communication device, comprising the light generating system as defined herein.

The lighting device may comprise a housing or a carrier, configured to house or support, one or more elements of the light generating system. Hence, in specific embodiments, the invention may provide a lighting device selected from the group of a lamp, a luminaire, and an optical wireless communication device, comprising the light generating system.

Instead of the terms “lighting device” or “lighting system”, and similar terms, also the terms “light generating device” or “light generating system”, (and similar terms), may be applied. A lighting device or a lighting system may be configured to generate device light (or “lighting device light”) or system light (“or lighting system light”). As indicated above, the terms light and radiation may interchangeably be used.

The lighting device may comprise a light source. The device light may in embodiments comprise one or more of light source light and converted light source light (such as luminescent material light).

The lighting system may comprise a light source. The system light may in embodiments comprise one or more of light source light and converted light source light (such as luminescent material light).

The term “centroid wavelength”, also indicated as λc, is known in the art, and refers to the wavelength value where half of the light energy is at shorter and half the energy is at longer wavelengths; the value is stated in nanometers (nm). It is the wavelength that divides the integral of a spectral power distribution into two equal parts as expressed by the formula λc=Σλ*I(λ)/(ΣI(λ)), where the summation is over the wavelength range of interest, and I(λ) is the spectral energy density (i.e. the integration of the product of the wavelength and the intensity over the emission band normalized to the integrated intensity). The centroid wavelength may e.g. be determined at operation conditions.

In a further aspect, the invention may provide an arrangement. In embodiments, the arrangement may comprise an indoor space and the lighting device configured as daylight. Additionally or alternatively, the arrangement may comprise the indoor space and the light generating system configured as daylight. The indoor space may in embodiments comprise one or more of a room in a house, an office, a restaurant, a hotel, a shopping center. However, other indoor spaces are herein not excluded. Hence, in specific embodiments, the invention may provide an arrangement comprising an indoor space and the lighting device or the light generating system configured as daylight.

The arrangement may be configured (and used) as artificial skylight or artificial wall light. Hence, the arrangement may be configured (and used) as artificial daylight (artificial daylight generating device).

Existing daylight generating systems may have problems with color uniformity and luminance gradients at the border of modules. Therefore, the present invention may provide a seamless daylight having less differences perceived in color and luminance.

Existing daylight generating systems may have an alternating sequence of cool white (CW) and warm white (WW) LEDs. In such systems, at ends of a light strip the color of the LED may be different. This may give visible color effects at the end of the light generating system (especially when light generating systems are positioned close to each other). Alternative systems may comprise alternating CW and WW LEDs having a central CW LED. However, when such light strips are configured perpendicular to one another, this may give color artefacts. Therefore the invention provides amongst others a system comprising clustered sets of colored LEDs to enhance color uniformity of artificial daylight. By clustering the LEDs in a “CW WW WW CW” set evenly distributed over the backlight the above mentioned disadvantages may be overcome and a good color and luminance distribution may be obtained. Such configuration may also provide good color uniformity in perpendicular positioned light strips, and so over the total light generating system.

In further embodiments, side emitting “TV” lenses may be used as backlighting. In this way, a small depth of the light generating system may be obtained and the system may be a modular approach for different sizes of daylight luminaires. As outcoupling window a Lambertian diffuser and beam shaping window may be used to comply to office regulations.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1a-d schematically depict embodiments of the invention.

FIG. 2a-c schematically depict further embodiments of the invention.

The schematic drawings are not necessarily to scale.

### DETAILED DESCRIPTION OF THE EMBODIMENTS

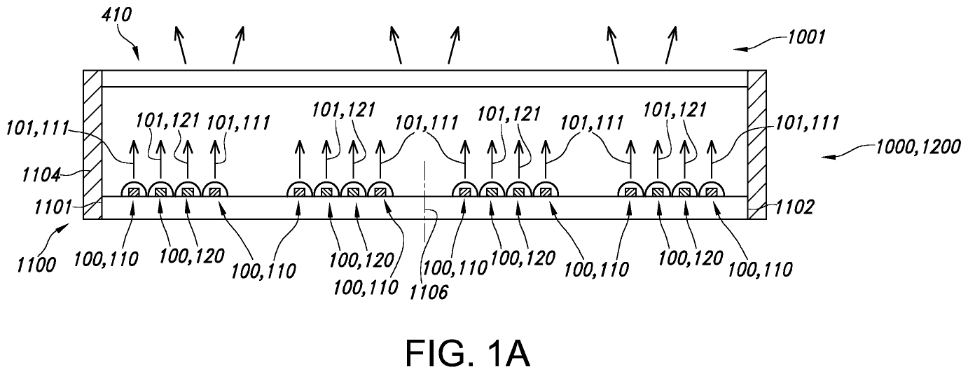

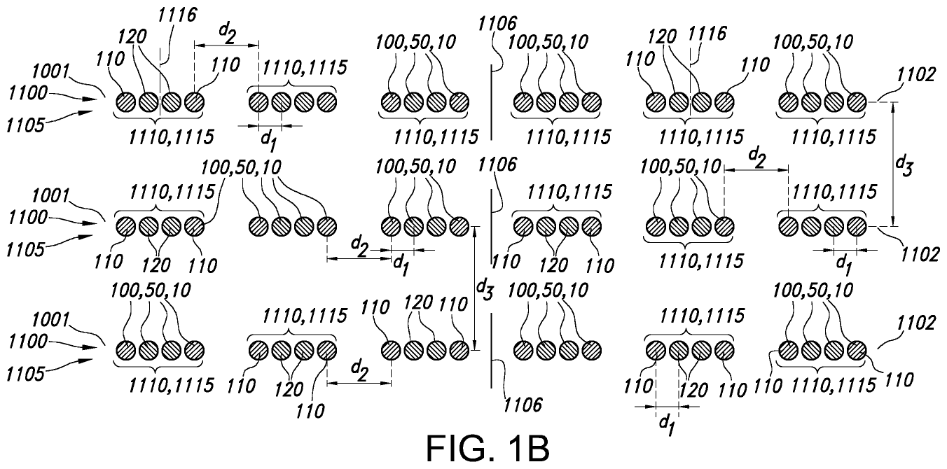

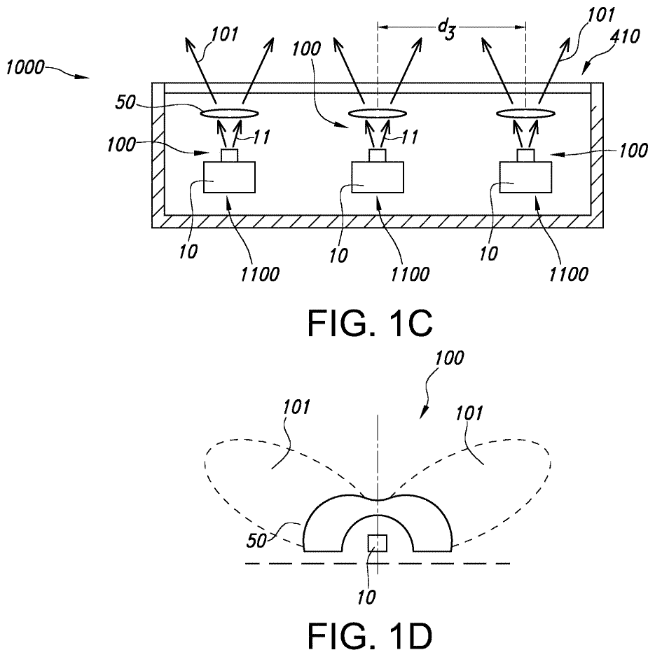

FIG. 1 schematically depicts embodiments of the light generating system 1000 comprising a plurality of n1 lighting modules 1100 and a diffuser element 410. FIG. 1a schematically depicts an embodiment of a lighting module 1100, wherein the lighting module 1100 comprises a first end 1101 and a second end 1102. In the depicted embodiment, the lighting module 1100 comprises walls 1104. The lighting module may comprise two types of light generating devices 100, especially a first type of light generating devices 110 and a second type of light generating devices 120. The light generating devices 100 may be configured to generate (in an operational mode) device light 101. The first type of light generating devices 110 may be configured to generate (in an operational mode) first device light 111. The second type of light generating devices 120 may be configured to generate (in an operational mode) second device light 121. The lighting module 1100 may in embodiments have a module middle position 1106. In embodiments, the diffuser element 410 may especially be configured downstream of the lighting module 1100. The diffuser element 410 may in embodiments be transmissive for at least part of the device light 101. In embodiments, the light generating system 1000 may be configured to generate system light 1001. Especially, the system light 1001 may in embodiments comprise diffused device light 101 emanating from the diffuser element 410.

FIG. 1b schematically depicts further embodiments of the light generating system 1000. In embodiments, each lighting module 1100 may comprise a module array 1105 of n2 sets 1110 of light generating devices 100. In embodiments n1≥2 and n2≥3. In the depicted embodiment n1=3 and n2=6. In further embodiments, each set 1110 may comprise a set array 1115 of n3 light generating devices 100. In embodiments, n3 may be selected from the range of 4≤n3<6. In the depicted embodiment, n3=4.

In further embodiments, each lighting module 1100 may comprise a module array 1105 wherein n2 may be selected from an even number. Especially, the module array 1105 may have a module middle position 1106. In the depicted embodiment, the module array 1105 is configured such that the set arrays 1115 are symmetrically configured relative to the module middle position 1106, with no set array 1115 at the module middle position 1106.

In embodiments, a first distance (d1) may be defined as a heart to heart distance between nearest neighboring solid state light sources 10 within a set array 1115. The first distance (d1) may in embodiments be selected from the range of 5-25 mm. In further embodiments, a second distance (d2) may be defined as a heart to heart distance between nearest neighboring solid state light sources 10 from different set arrays 1115 within the same lighting module 1100. In embodiments, the second distance (d2) may be selected from the range of 20-75 mm. Additionally or alternatively, the first distance (d1) may in embodiments be smaller than the second distance (d2). In embodiments, a third distance (d3) may be defined as a heart to heart distance between nearest neighboring solid state light sources 10 from different set arrays 1115 from different lighting modules 1100. The third distance (d3) may in embodiments be selected from the range of 50-140 mm.

In the depicted embodiment, the light generating devices 100 may in embodiments comprise two types of light generating devices 100. In embodiments, the two types of light generating devices 100 may differ in spectral distributions of the (beam shaped) device light 101. In further embodiments, the two types of light generating devices 100 may be positioned symmetrically in the set array 1115. In the depicted embodiment, the first type of light generating devices 110 and the second type of light generating devices 120 in each set array 1115 may be configured in an ABBA or BAAB configuration.

In embodiments, the first type of light generating devices 110 may be configured to generate first device light 111. In specific embodiments, the first device light 111 may be warm white first device light 111. Additionally or alternatively, the second type of light generating devices 120 configured to generate cool white second device light 121. In specific embodiments, the second device light 121 may be cool white second device light 121. In specific embodiments, the warm white first device light 111 and the cool white second device light 121 may have a difference in correlated color temperature of at least 500 K. In further embodiments, the warm white first device light 111 may have a first correlated color temperature CCT1 selected from the range of 1800-3500 K. Additionally or alternatively, the cool white second device light 121 may in embodiments have a second correlated color temperature CCT2 selected from the range of at least 3500 K.

FIG. 1c schematically depicts the light generating device 100 comprising a solid state light source 10 and a lens 50. Especially, the solid state light source 10 may be configured to generate light source light 11. In embodiments, the lens 50 may be configured downstream of the solid state light source 10 and configured to beam shape the light source light 11 into beam shaped device light 101.

FIG. 1d schematically depicts the light source 10 and the lens 50 wherein the lens 50 comprises a side-emitting lens. In such embodiments, the light generating devices 100 may be side-emitting light generating devices 100.

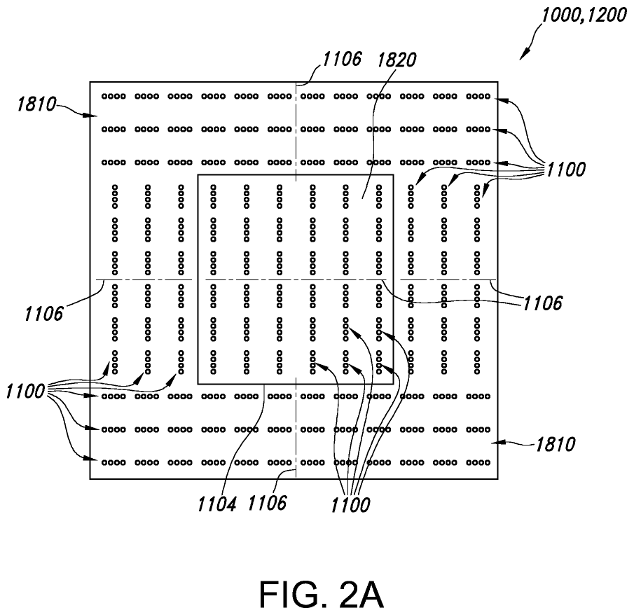

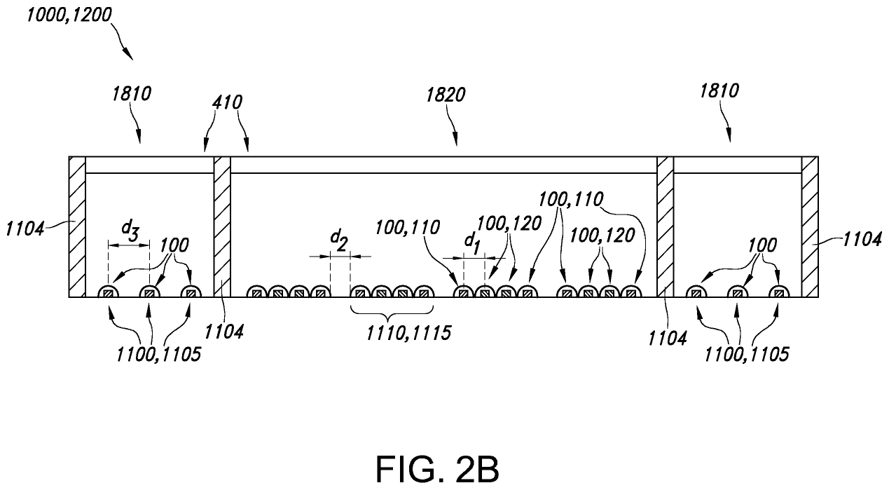

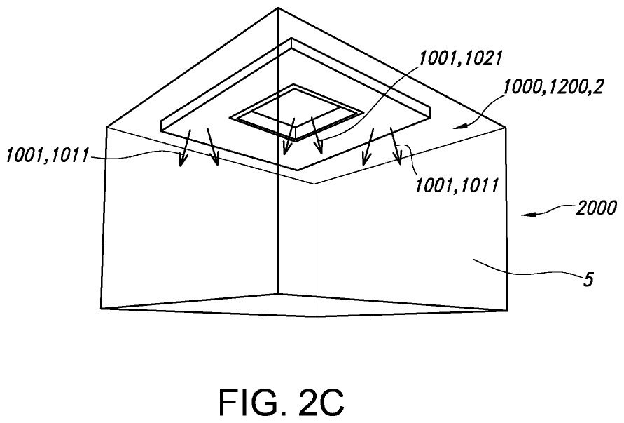

FIG. 2a schematically depicts an embodiment of the light generating system 1000 wherein the light generating system 1000 comprises a first light emitting part 1810 and a second light emitting part 1820. In embodiments, the first light emitting part 1810 may enclose the second light emitting part 1820. In further embodiments, the first light emitting part 1810 may comprise the plurality of n1 lighting modules 1100 and the diffuser element 410. In yet further embodiments, the second light emitting part 1810 may comprise the plurality of n1 lighting modules 1100 and the diffuser element 410. In specific embodiments, the first light emitting part 1810 may comprise the (primary) first type of light generating devices 110 configured to provide warm white first device light 111 and the (primary) second type of light generating devices 120 configured to provide cool white second device light 121, and the second light emitting part 1820 may comprise the (secondary) first type of light generating devices 110 configured to provide blue first device light 111 and the (secondary) second type of light generating devices 120 configured to provide cool white second device light 121.

In the depicted embodiment, at least two lighting modules 1100 are configured orthogonal to each other. Also in the depicted embodiment, at least two lighting modules 1100 are configured parallel to each other. Each set array 1115 may have a set array middle position 1116. In the depicted embodiment, one of the first end 1101 and the second end 1102 of one of the lighting modules 1102 is directed at a set array middle position 1116 of one of the set arrays 1115 of the other lighting module 1100. In alternative embodiments, one of the first end 1101 and the second end 1102 of one of the lighting modules 1102 may be directed at the module middle position 1106 of the other lighting module 1100.

FIG. 2b schematically depicts an cross section of the light generating system 1000 wherein the light generating system 1000 comprises a first light emitting part 1810 and a second light emitting part 1820 as depicted in FIG. 2a.

FIG. 2c schematically depicts an application of the light generating system 1000. In embodiments, a lighting device 1200 selected from the group of a lamp 1, a luminaire 2, and an optical wireless communication device, may comprise the light generating system 1000. In the depicted embodiment, an arrangement 2000 comprises an indoor space 5 and the lighting device 1200 or the light generating system 1000 is configured as daylight. In embodiments, the light generating system 1000 may be configured to generate system light 1001. Especially, a part of the light generating system may be configured to generate primary system light 1011. Additionally or alternatively, a part of the light generating system may be configured to generate secondary system light 1021.

The term “plurality” refers to two or more. The terms “substantially” or “essentially” herein, and similar terms, will be understood by the person skilled in the art.

The terms “substantially” or “essentially” may also include embodiments with “entirely”, “completely”, “all”, etc. Hence, in embodiments the adjective substantially or essentially may also be removed. Where applicable, the term “substantially” or the term “essentially” may also relate to 90% or higher, such as 95% or higher, especially 99% or higher, even more especially 99.5% or higher, including 100%. The term “comprise” also includes embodiments wherein the term “comprises” means “consists of”. The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”. Use of the verb “to comprise” and its conjugations does not exclude the presence of elements or steps other than those stated in a claim. Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”. The article “a” or “an” preceding an element does not exclude the presence of a plurality of such elements.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices, apparatus, or systems may herein amongst others be described during operation. As will be clear to the person skilled in the art, the invention is not limited to methods of operation, or devices, apparatus, or systems in operation.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

The invention may be implemented by means of hardware comprising several distinct elements, and by means of a suitably programmed computer. In a device claim, or an apparatus claim, or a system claim, enumerating several means, several of these means may be embodied by one and the same item of hardware. The mere fact that certain measures are recited in mutually different dependent claims does not indicate that a combination of these measures cannot be used to advantage. In yet a further aspect, the invention (thus) provides a software product, which, when running on a computer is capable of bringing about (one or more embodiments of) the method as described herein.

The invention also provides a control system that may control the device, apparatus, or system, or that may execute the herein described method or process. Yet further, the invention also provides a computer program product, when running on a computer which is functionally coupled to or comprised by the device, apparatus, or system, controls one or more controllable elements of such device, apparatus, or system.

The invention further applies to a device, apparatus, or system comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

1. A light generating system comprising a plurality of n1 lighting modules and a diffuser element, wherein:
each lighting module comprises a module array of n2 sets of light generating devices; wherein n1≥2 and n2≥4;
each light generating device comprises a solid state light source and a lens, wherein the solid state light source is configured to generate light source light, wherein the lens is configured downstream of the solid state light source and configured to beam shape the light source light into beam shaped device light;
each set comprises a set array of n3 light generating devices comprising two types of light generating devices, wherein the two types of light generating devices comprise a first type of light generating devices and a second type of light generating devices, wherein the two types of light generating devices differ in spectral distributions of the device light, and wherein the two types of light generating devices are positioned symmetrically in the set array wherein n3 is selected from the range of 4≤n3≤6;
a first distance between solid state light sources within a set array is smaller than a second distance between solid state light sources from different set arrays
the diffuser element is configured downstream of the n1 lighting modules; wherein the diffuser element is transmissive for at least part of the device light;
the light generating system is configured to generate system light, wherein the system light comprises diffused device light emanating from the diffuser element;
each lighting module comprises a module array wherein n2 is selected from an even number, wherein the module array has a module middle position; and wherein the module array is configured such that the set arrays are symmetrically configured relative to the module middle position, with no set array at the module middle position; and
at least two lighting modules are configured orthogonal to each other.

2. The light generating system according to claim 1, wherein the first type of light generating devices and the second type of light generating devices in each set array are configured in an ABBA or BAAB configuration; and wherein n1≥6 and n2≥6.

3. The light generating system according to claim 1, wherein n2≥10.

4. The light generating system according to claim 1, wherein the first type of light generating devices and the second type of light generating devices in each set array are configured in a BAAB configuration.

5. The light generating system according to claim 3, wherein each set array has a set array middle position; wherein each lighting module comprises a first end and a second end, wherein one of the first end and the second end of one of the lighting modules is directed at (i) either a set array middle position of one of the set arrays of the other lighting module, (ii) or the module middle position of the other lighting module.

6. The light generating system according to claim 1, wherein the first distance, defined as a heart to heart distance between nearest neighboring solid state light sources within a set array, is selected from the range of 5-25 mm.

7. The light generating system according to claim 1, wherein the second distance, defined as a heart to heart distance between nearest neighboring solid state light sources from different set arrays within the same lighting module, is selected from the range of 20-75 mm.

8. The light generating system according to claim 1, wherein a third distance, defined as a heart to heart distance between nearest neighboring solid state light sources from different set arrays from different lighting modules, is selected from the range of 50-140 mm.

9. The light generating system according to claim 1, wherein the light generating devices are side-emitting light generating devices.

10. The light generating system according to claim 1, wherein the first type of light generating devices are configured to generate warm white first device light and the second type of light generating devices are configured to generate cool white second device light, wherein the warm white first device light and the cool white second device light have a difference in correlated color temperature of at least 500 K.

11. The light generating system according to claim 10, wherein the warm white first device light has a first correlated color temperature CCT1 selected from the range of 1800-3500 K, and wherein the cool white second device light has a second correlated color temperature CCT2 selected from the range of at least 3500 K.

12. The light generating system according to claim 1, comprising a first light emitting part and a second light emitting part, wherein:
the first light emitting part encloses the second light emitting part;
the first light emitting part comprises the plurality of n1 lighting modules and the diffuser element;
the first light emitting part is configured to provide primary system light;
the second a light emitting part is configured to provide secondary system light; and
the system light comprises one or more of the primary system light and the secondary system light.

13. The light generating system according to claim 12, wherein the first light emitting part comprises the first type of light generating devices and the second type of light generating devices; wherein the second light emitting part comprises the first type of light generating devices and the second type of light generating devices, wherein the first type of light generating devices and the second type of light generating devices of the second light emitting part are selected from light generating devices configured to generate blue device light and light generating devices configured to generate cool white device light having a correlated color temperature selected from the range of at least 3500 K; wherein the second light emitting part shares the diffuser element or wherein the second light emitting part comprises a second diffuser element.

14. A lighting device selected from the group of a lamp, a luminaire, and an optical wireless communication device, comprising the light generating system according to claim 1.

15. An arrangement comprising an indoor space and the lighting device according claim 14 configured as artificial daylight.
